(19) United States
(12) Patent Application Publication
(10) Pub. No.: US 2022/0187712 A1
(43) Pub. Date: Jun. 16, 2022

(54) COMPOSITION FOR AVOIDING PATTERN COLLAPSE WHEN TREATING PATTERNED MATERIALS WITH LINE-SPACE DIMENSIONS OF 50 NM OR BELOW COMPRISING A BORON-TYPE ADDITIVE

(71) Applicant: BASF SE, Ludwigshafen am Rhein (DE)

(72) Inventors: Szilard Csihony, Ludwigshafen (DE); Daniel Loeffler, Ludwigshafen (DE); Marcel Brill, Ludwigshafen (DE); Frank Pirrung, Ludwigshafen (DE); Lothar Engelbrecht, Berlin (DE); Maike Bergeler, Ludwigshafen (DE); Paatrick Wilke, Ludwigshafen (DE); Yeni Burk, Ludwigshafen (DE); Volodymyr Boyko, Ludwigshafen (DE)

(21) Appl. No.: 17/603,250

(22) PCT Filed: Apr. 3, 2020
(86) PCT No.: PCT/EP2020/059580

§ 371 Date: Oct. 12, 2021

(30) Foreign Application Priority Data
Apr. 16, 2019 (EP) 19169513.9

(51) Int. Cl. G03F 7/40; C11D 11/00; C11D 7/50; C11D 7/26; H01L 21/02

(52) U.S. Cl. CPC G03F 7/405; C11D 11/0047; H01L 21/02057; C11D 7/26; C11D 7/5022

(57) ABSTRACT

Described herein is a non-aqueous composition including
(a) an organic solvent, and
(b) at least one additive of formulae I,

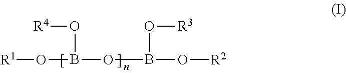

where R¹, R², R³, and R⁴ are independently selected from C₁ to C₁₀ alkyl, C₁ to C₁₁ alkylcarbonyl, C₆ to C₁₂ aryl, C₇ to C₁₄ alkylaryl, and C₇ to C₁₄ arylalkyl; and n is 0 or 1.

Composition for avoiding pattern collapse when treating patterned materials with line-space dimensions of 50 nm or below comprising a boron-type additive.

The present invention is directed to a composition for anti-pattern-collapse treatment, its use for and a process for manufacturing integrated circuits devices, optical devices, micromachines and mechanical precision devices.

### BACKGROUND OF THE INVENTION

In the process of manufacturing ICs with LSI, VLSI and ULSI, patterned material layers like patterned photoresist layers, patterned barrier material layers containing or consisting of titanium nitride, tantalum or tantalum nitride, patterned multi-stack material layers containing or consisting of stacks e.g. of alternating polysilicon and silicon dioxide or silicon nitride layers, and patterned dielectric material layers containing or consisting of silicon dioxide or low-k or ultra-low-k dielectric materials are produced by photolithographic techniques. Nowadays, such patterned material layers comprise structures of dimensions even below 22 nm with high aspect ratios.

Irrespective of the exposure techniques the wet chemical processing of small patterns however involves a plurality of problems. As technologies advance and dimension requirements become stricter and stricter, patterns are required to include relatively thin and tall structures or features of device structures i.e., features having a high aspect ratio, on the substrate. These structures may suffer from bending and/or collapsing, in particular, during the spin dry process, due to excessive capillary forces of the liquid or solution of the rinsing liquid deionized water remaining from the chemical rinse and spin dry processes and being disposed between adjacent patterned structures.

Due to the shrinkage of the dimensions, the removal of particles and plasma etch residues in order to achieve a defect free patterned structure becomes also a critical factor. This does apply to photoresist patterns but also to other patterned material layers, which are generated during the manufacture of optical devices, micromachines and mechanical precision devices.

WO 2012/027667 A2 discloses a method of modifying a surface of a high aspect ratio feature by contacting the surface of the high aspect ratio feature with an additive composition to produce a modified surface, wherein forces acting on the high aspect ratio feature when a rinse solution is in contact with the modified surface are sufficiently minimized to prevent bending or collapse of the high aspect ratio feature at least during removal of the rinse solution or at least during drying of the high aspect ratio feature.

WO 2019/086374 discloses a non-aqueous composition comprising a siloxane-type anti pattern collapse additive. Unpublished European patent application No. 18190173.7 discloses a non-aqueous composition comprising a phosphonic acid-type additive. Unpublished European patent application No. 19168153.5 discloses a non-aqueous composition comprising an ammonia-activated H-silane-type additive.

However, there is still a need for a composition that effectively prevents pattern collapse of sub 50 nm structures.

It is an object of the present invention to provide a method for manufacturing integrated circuits for nodes of 50 nm and lower, in particular for nodes of 32 nm and lower and, especially, for nodes of 22 nm and lower, which method no longer exhibits the disadvantages of prior art manufacturing methods.

In particular, the compounds according to the present invention shall allow for the chemical rinse of patterned material layers comprising patterns with a high aspect ratio and line-space dimensions of 50 nm and less, in particular, of 32 nm and less, especially, of 22 nm and less, without causing pattern collapse.

### SUMMARY OF THE INVENTION

The present invention completely avoids, all the disadvantages of the prior art by using a non-aqueous composition comprising an organic solvent in combination with a boron-type non-ionic additive as described herein.

A first embodiment of the present invention is a non-aqueous composition comprising

(a) an organic solvent

(b) at least one additive of formulae I

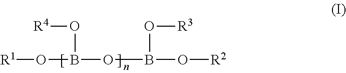

wherein R¹, R², R³, and R⁴ are independently selected from C₁ to C₁₀ alkyl, C₁ to C₁₁ alkylcarbonyl, C₆ to C₁₂ aryl, C₇ to C₁₄ alkylaryl, and C₇ to C₁₄ arylalkyl; and n is 0 or 1.

Another embodiment of the present invention is the use of the compositions described herein for treating substrates having patterned material layers having line-space dimensions of 50 nm or below, aspect ratios of greater or equal 4, or a combination thereof.

Yet another embodiment of the present invention is a method for manufacturing integrated circuit devices, optical devices, micromachines and mechanical precision devices, the said method comprising the steps of
(1) providing a substrate having patterned material layers having line-space dimensions of 50 nm or below, aspect ratios of greater or equal 4, or a combination thereof,
(2) contacting the substrate at least once with the non-aqueous composition as described herein, and
(3) removing the non-aqueous composition from the contact with the substrate.

The compositions comprising an organic solvent, preferably an alcohol, in combination and a boron-type additive is particularly useful for anti-pattern-collapse treatment of substrates comprising patterns having line-space dimensions of 50 nm or less, particularly of 32 nm or less and, most particularly 22 nm or less. Furthermore, the compositions according to the invention is particularly useful for aspect ratios greater or equal 4 without causing pattern collapse. Last not least, if protic organic solvent, particularly alcohols are used as the solvent, the composition has an excellent compatibility with substrates comprising polyvinyl chloride.

The cleaning or rinsing solutions comprising a polar solvent in combination with a boron-type additive are generally useful for avoiding pattern collapse of photoresist structures as well as of non-photoresist patterns with high aspect ratios stacks (HARS), particularly patterned multi-stack material layers containing or consisting of stacks comprising alternating polysilicon and silicon dioxide or silicon nitride layers.

### DETAILED DESCRIPTION OF THE INVENTION

The present invention is directed to a composition particularly suitable for manufacturing patterned materials comprising sub 50 nm sized features like integrated circuit (IC) devices, optical devices, micromachines and mechanical precision devices, in particular IC devices.

Any customary and known substrates used for manufacturing IC devices, optical devices, micromachines and mechanical precision devices can be used in the process of the invention. Preferably, the substrate is a semiconductor substrate, more preferably a silicon wafer, which wafers are customarily used for manufacturing IC devices, in particular IC devices comprising ICs having LSI, VLSI and ULSI.

The composition is particularly suitable for treating substrates having patterned material layers having line-space dimensions of 50 nm and less, in particular, 32 nm and less and, especially, 22 nm and less, i.e. patterned material layers for the sub-22 nm technology nodes. The patterned material layers preferably have aspect ratios above 4, preferably above 5, more preferably above 6, even more preferably above 8, even more preferably above 10, even more preferably above 12, even more preferably above 15, even more preferably above 20. The smaller the line-space dimensions and the higher the aspect ratios are the more advantageous is the use of the composition described herein.

The composition according to the present invention may be applied to substrates of any patterned material as long as structures tend to collapse due to their geometry.

By way of example, the patterned material layers may be
(a) patterned silicon oxide or silicon nitride coated Si layers,
(b) patterned barrier material layers containing or consisting of ruthenium, cobalt, titanium nitride, tantalum or tantalum nitride,
(c) patterned multi-stack material layers containing or consisting of layers of at least two different materials selected from the group consisting of silicon, polysilicon, silicon dioxide, SiGe, low-k and ultra-low-k materials, high-k materials, semiconductors other than silicon and polysilicon, and metals, and
d) patterned dielectric material layers containing or consisting of silicon dioxide or low-k or ultra-low-k dielectric materials.

Organic Solvent

The anti-pattern-collapse composition comprises an organic solvent, preferably a polar protic organic solvent.

Surprisingly it was found that even low amounts of water may influence the performance of the anti-pattern-collapse capability of the subject compositions. It is therefore important that the compositions, essentially the organic solvent(s) present in the compositions according to the present invention are non-aqueous. Due to its hygroscopicity polar protic organic solvents like isopropanol usually has a rather high amount of residual water unless removed by drying.

As used herein, “non-aqueous” means that the composition may only contain low amounts of water up to about 1% by weight. Preferably the non-aqueous composition comprises less than 0.5% by weight, more preferably less than 0.2% by weight, even more preferably less than 0.1% by weight, even more preferably less than 0.05% by weight, even more preferably less than 0.02% by weight, even more preferably less than 0.01% by weight, even more preferably less than 0.001% by weight of water. Most preferably essentially no water is present in the composition. “Essentially” here means that the water present in the composition does not have a significant influence on the performance of the additive in the non-aqueous solution with respect to pattern collapse of the substrates to be treated.

The organic solvents need to have a sufficiently low boiling point to be removed by heating without negatively impacting the substrate treated with the composition. For typical substrates, the boiling point of the organic solvent should be 150° C. or below, preferably 100° C. or below.

It is preferred that the solvent essentially consists of one or more organic solvents, which may be protic or aprotic organic solvents. Preferred are one or more polar protic organic solvents, most preferred a single polar protic organic solvent.

As used herein a “polar aprotic organic solvent” is an organic solvent which has no acidic hydrogen (i.e. that does not contain or cannot donate a hydrogen ion), has a dipole moment of 1.7 or more.

Typical polar aprotic organic solvents are (a), without limitation, ketones, such as but not limited to acetone, (b) lactones , such as but not limited to y-butyrolactone, (c) lactames, such as but not limited to N-methyl-2-pyrrolidone, (d) nitriles, such as but not limited to acetonitrile, (e) nitro compounds, such as but not limited to nitromethane, (f) tertiary carboxylic acid amides, such as but not limited to dimethylformamide, (g) urea derivates, such as but not limited to tetramethyl urea or dimethylpropylene urea (DMPU), (h) sulfoxides, such as but not limited to dimethylsulfoxid (DMSO), (i) sulfone, such as but not limited to sulfolane, (h) carbonic acid esters, such as but not limited to dimethylcarbonate or ethylencarbonate.

As used herein a “polar protic organic solvent” is an organic solvent which comprises an acidic hydrogen (i.e. that can donate a hydrogen ion).

Typical polar protic organic solvents are, without limitation, (a) C₁ to C₁₀ alcohols, (b) primary or secondary amines, carboxylic acids, such as but not limited to formic acid or acetic acid, or (c) primary or secondary amides, such as but not limited to formamide.

Preferred organic solvents are linear, branched or cyclic aliphatic alcohols, particularly linear or branched alkanols, which comprise at least one hydroxy group. Preferred alkanols are methanol, ethanol, 1-propanol, 2-propanol (isopropanol) or butanols. Most preferred is 2-propanol.

Additives of Formula I

The boric acid ester additive according to the present invention (also referred to as additive or more specifically as boron alkoxylate or boron aroxylate) may be selected from formula I:

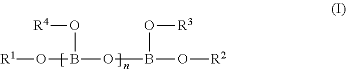

Herein R¹, R², R³, and R⁴ may be independently selected from C₁ to C₁₀ alkyl, C₁ to C₁₁ alkylcarbonyl, C₆ to C₁₂ aryl, C₇ to C₁₄ alkylaryl, and C₇ to C₁₄ arylalkyl. Preferably R¹, R², R³, and R⁴ may be selected from C₁ to C₈ alkyl, C₁ to C9 alkylcarbonyl, C₆ to C₁₉ aryl, C₇ to C₁₂ alkylaryl, and C₇ to C₁₂ arylalkyl. More preferably R¹, R², R³, and R⁴ may be selected from C₁ to C₆ alkyl, C₁ to C₇ alkylcarbonyl, phenyl, C₇ to C10 alkylaryl, and C₇ to C₁₀ arylalkyl. Even more preferably R¹, R², R³, and R⁴ may be selected from C₁ to C₄ alkyl, C₁ to C₅ alkylcarbonyl, phenyl, C₇ to C₈ alkylaryl, and C₇ to C₈ arylalkyl. Most preferred groups R¹, R², R³, and R⁴ may be selected from methyl, ethyl, 1-propyl, 2-propyl, acetyl, phenyl.

n may be 0 or 1, preferably 0.

In a particular preferred embodiment the additive is selected from boron triacetate, tribenzyl borate, trimethoxy borate, triethoxy borate, and tri-2-propoxy borate.

The concentration should be sufficiently high to properly prevent pattern collapse but should be as low as possible for economic reasons. The concentration of the additives of formulae I, II, III and IV in the non-aqueous solution may generally be in the range of about 0.00005 to about 3% by weight. Preferably the concentration of the additive if from about 0.00005 to about 1.0% by weight, more preferably from about 0.0005 to about 0.5% by weight, even more preferably from 0.0005 to 0.1% by weight, even more preferably from 0.001 to 0.1% by weight, and most preferably 0.002 to 0.1% by weight, the weight percentages being based on the overall weight of the composition.

There may be one or more additives in the composition, however it is preferred to use only one additive of formula I.

Further Additives

Further additive may be present in the cleaning solution according to the present invention. Such additives may be
(I) buffer components for pH adjustment such as but not limited to (NH₄)₂CO₃/NH₄OH, Na₂CO₃/NaHCO₃, tris-hydroxymethyl-aminomethane/HCl, Na₂HPO_{4/}NaH₂PO₄, or organic acids like acetic acid etc., methanesulfonic acid,
(II) one or more further additives, either non-ionic, or, anionic to improve surface tension and solubility of the mixture, or
(III) dispersants to prevent the surface re-attachment of the removed particles of dirt or polymer.

Preferably the non-aqueous composition consists essentially of the organic solvent, preferably the polar protic organic solvent, and the at least one additive of formula I.

Application

The compositions described herein may be used for treating substrates having patterned material layers having line-space dimensions of 50 nm or below, aspect ratios of greater or equal 4, or a combination thereof.

The compositions described herein may be used in a method for manufacturing integrated circuit devices, optical devices, micromachines and mechanical precision devices, the method comprising the steps of
(1) providing a substrate having patterned material layers having line-space dimensions of 50 nm and less and aspect ratios of greater or equal 4,
(2) contacting the substrate at least once with the non-aqueous solution containing at least a boric acid ester additive as described herein, and
(3) removing the aqueous solution from the contact with the substrate.

Preferably the substrate is provided by a photolithographic process comprising the steps of
(i) providing the substrate with an immersion photoresist, EUV photoresist or eBeam photoresist layer,
(ii) exposing the photoresist layer to actinic radiation through a mask with or without an immersion liquid,
(iii) developing the exposed photoresist layer with a developer solution to obtain a pattern having line-space dimensions of 32 nm and less and an aspect ratio of 10 or more,
(iv) applying the non-aqueous composition described herein to the developed patterned photoresist layer, and
(v) spin drying the semiconductor substrate after the application of the non-aqueous composition.

Any customary and known immersion photoresist, EUV photoresist or eBeam photoresist may be used. The immersion photoresist may already contain at least one of the additives or a combination thereof. Additionally, the immersion photoresist may contain other nonionic additives. Suitable nonionic additives are described, for example, in US 2008/0299487 A1, page 6, paragraph [0078]. Most preferably, the immersion photoresist is a positive resist.

Beside e-Beam exposure or extreme ultraviolet radiation of approx. 13.5 nm, preferably, UV radiation of the wavelength of 193 nm is used as the actinic radiation.

In case of immersion lithography, preferably ultra-pure water is used as the immersion liquid.

Any customary and known developer solution can be used for developing the exposed photoresist layer. Preferably, aqueous developer solutions containing tetramethylammonium hydroxide (TMAH) are used.

Preferably, the chemical rinse solutions are applied to the exposed and developed photoresist layers as puddles.

In the third step of the method the non-aqueous solution is removed from the contact with the substrate. Any known methods customarily used for removing liquids from solid surfaces can be employed.

It is essential for photolithographic process according to the method of the invention, that the chemical rinse solution contains at least one of the siloxane additives.

Customary and known equipment customarily used in the semiconductor industry can be used for carrying out the photolithographic process in accordance with the method of the invention.

Examples

Patterned silicon wafers with a circular nano pillar pattern were used to determine the pattern collapse performance of the formulations during drying. The (aspect ratio) AR 20 pillars used for testing have a height of 600 nm and a diameter of 30 nm. The pitch size is 90 nm. 1×1 cm wafer pieces where processed in the following sequence without drying in between:
30 s Dilute Hydrofluoric Acid (DHF) 0.9% dip,
60 s ultra-pure water (UPVV) dip,
60 s isopropanol (IPA) dip,
60 s dip of a solution of the respective additive in the solvent at room temperature,
60 s IPA dip,
N₂ blow dry.

The water content of the solvent was below 0,01% by weight.

The compositions of table 1 were used in the example.

TABLE 1

| | | Conc. | Organic |
|---|---|---|---|
| Example | Additive | [wt %] | Solvent |
| Comp. 1 | n/a | 0 | isopropanol |
| 2 | tri-2-propoxy borate | 0.05 | isopropanol |

The dried silicon wafers where analyzed with top down SEM and the collapse statistics for examples 1 and 2 are shown in table 2.

The pattern collapse Cluster Size Distribution was determined from the SEM images. The cluster size corresponds to number of uncollapsed pillars the respective cluster consist of. By way of example, if the wafer before treatment comprises 4×4 pillars and 8 remain uncollapsed, 4 collapse into two clusters comprising 2 pillars and 4 pillars collapse into one cluster comprising 4 pillars the ratio would be 8/11 single clusters, 2/11 double clusters and 1/11 clusters with four pillars.

TABLE 2

| | Cluster Size Distribution in collapsed structures [%] | | | |
|---|---|---|---|---|
| Example | 1 | 2 | 3-4 | >5 |
| Comp. 1 | 4.9 | 25.3 | 69.1 | 0.7 |
| 2 | 13.4 | 42.3 | 44.0 | 0.3 |

Table 2 shows that additives have a beneficial effect on the degree of pattern collapse compared to the solution without any additive.

1. A method of using a non-aqueous composition comprising
(a) an organic solvent; and
(b) at least one additive of formulae I; 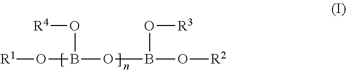
wherein R¹, R², R³, and R⁴ are independently selected from the group consisting of C₁ to C₁₀ alkyl, C₁ to C₁₁ alkylcarbonyl, C₆ to C₁₂ aryl, C₇ to C₁₄ alkylaryl, and C₇ to C₁₄ arylalkyl; and n is 0 or 1, the method comprising using the non-aqueous composition for treating substrates having patterned material layers having line-space dimensions of 50 nm or below, aspect ratios of greater or equal 4, or a combination thereof.

2. The method of use according to claim 1, wherein the organic solvent is a polar protic organic solvent.

3. The method of use according to claim 1, wherein the organic solvent is a linear or branched C₁ to C₁₀ alkanol.

4. (canceled)

5. The method of use according to claim 1, wherein the content of water in the non-aqueous composition is lower than 0.1% by weight.

6. The method of use according to claim 1, wherein the non-aqueous composition consists essentially of the organic solvent and the at least one additive of formula I.

7. The composition method of use according to claim 1, wherein R¹, R², R³, and R⁴ are selected from the group consisting of C₁ to C₆ alkyl, C₁ to C₇ alkylcarbonyl, phenyl, C₇ to C₁₀ alkylaryl, and C₇ to C₁₀ arylalkyl.

8. The method of use according to claim 1, wherein n is 0.

9. The method of use according to claim 1, wherein the additive is selected from the group consisting of boron triacetate, tribenzyl borate, trimethoxy borate, triethoxy borate, and tri-2-propoxy borate.

10. (canceled)

11. A method for manufacturing integrated circuit devices, optical devices, micromachines and mechanical precision devices, the said method comprising the steps of
(1) providing a substrate having patterned material layers having line-space dimensions of 50 nm or below, aspect ratios of greater or equal 4, or a combination thereof,
(2) contacting the substrate at least once with a non-aqueous composition comprising
(a) an organic solvent; and
(b) at least one additive of formulae I; 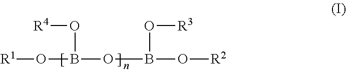
wherein R¹, R², R³, and R⁴ are independently selected from the group consisting of C₁ to C₁₀ alkyl, C₁ to C₁₁ alkylcarbonyl, C₆ to C₁₂ aryl, C₇ to C₁₄ alkylaryl, and C₇ to C₁₄ arylalkyl; and n is 0 or 1, and
(3) removing the non-aqueous composition from the contact with the substrate.

12. The method according to claim 11, wherein the patterned material layers have line-space dimensions of 32 nm or less and aspect ratios of 10 or more.

13. The method according to claim 11, wherein the patterned material layers are selected from the group consisting of patterned developed photoresist layers, patterned barrier material layers, patterned multi-stack material layers and pattern dielectric material layers.

14. The process according to claim 11, wherein the organic solvent is a polar protic organic solvent.

15. The process according to claim 11, wherein the organic solvent is a linear or branched C1 to C10 alkanol.

16. The process according to claim 11, wherein the additive is selected from the group consisting of boron triacetate, tribenzyl borate, trimethoxy borate, triethoxy borate, and tri-2-propoxy borate.
